(19) United States
(12) Patent Application Publication
(10) Pub. No.: US 2011/0083891 A1
(43) Pub. Date: Apr. 14, 2011

(54) ELECTRONIC COMPONENT-EMBEDDED PRINTED CIRCUIT BOARD AND METHOD OF MANUFACTURING THE SAME

(76) Inventors: Hong Bok WE, Gyunggi-do (KR); Tae Sung JEONG, Gyunggi-do (KR); Dae Jun KIM, Gyunggi-do (KR)

(21) Appl. No.: 12/631,555

(22) Filed: Dec. 4, 2009

(30) Foreign Application Priority Data
Oct. 12, 2009 (KR) 10-2009-0096913

(51) Int. Cl. H05K 1/18; B29C 65/00; B23K 31/02

(52) U.S. Cl. 174/260; 156/280

(57) ABSTRACT

Disclosed herein is an electronic component-embedded printed circuit board, including: a flexible film; an insulation layer formed on one side of the flexible film; an electronic component mounted on the one side of the flexible film in a face-down manner such that the electronic component is buried in the insulation layer; and a circuit layer including a connecting pattern which is formed on the one side of the flexible film and is connected with a connecting terminal of the electronic component by a connecting member. The electronic component-embedded printed circuit board is advantageous in that the position alignment between the connecting patterns and the connecting terminals is easy and the connection reliability therebetween is high because the connecting patterns formed on a flexible film are directly connected to the connecting terminals of an electronic component using connecting members, and in that the production cost thereof can be reduced because additional rewiring is not required.

### CROSS REFERENCE TO RELATED APPLICATION

This application claims the benefit of Korean Patent Application No. 10-2009-0096913, filed Oct. 12, 2009, entitled “A Printed Circuit Board Comprising Embedded Electronic Component Within and A Method For Manufacturing The Same”, which is hereby incorporated by reference in its entirety into this application.

### BACKGROUND OF THE INVENTION

1. Technical Field

The present invention relates to an electronic component-embedded printed circuit board and a method of manufacturing the same.

2. Description of the Related Art

Various technologies are required to realize a printed circuit board in a market which requires semiconductor packages having decreased profiles and a variety of functions.

For example, in the manufacturing of a flip chip ball grid array (FCBGA) package, the electroconductive terminals or lands of ICs are directly soldered to the lands corresponding to the die bonding region on the surface of a substrate using reflowable solder bumps or balls. In this case, electronic components are functionally connected to other elements of an electronic system through electroconductive channels including substrate traces, and the substrate traces generally serve to transport the signals transmitted between electronic components such as ICs and the like. In the case of FCBGA, ICs located at the upper end of a substrate and capacitors located at the lower end thereof are surface-mounted, respectively. In this case, the length of a circuit path for connecting the IC with the capacitor, that is, a connection circuit, is increased by the thickness of the substrate, so that impedance is increased, thereby deteriorating electrical performance. Further, since a part of the lower end of the substrate must be used to mount chips, design flexibility is limited, for example, users desiring to mount a ball array over the entire surface of the lower end thereof will be left unsatisfied.

In order to solve the above problems, electronic component packaging to technologies for shortening the circuit path by embedding electronic components in a substrate are becoming popular. Since electronic component-embedded printed circuit boards (PCBs) are provided in the organic substrate thereof with active/passive electronic components mounted on a conventional substrate in the form of package, a kind of next-generation three dimensional packaging technology, which can satisfy the multi-functionality attributable to the insurance of residual surface area, the low loss of high frequency/high efficiency attributable to the minimization of signal transfer lines, and the miniaturization of the printed circuit board, can be developed, and a novel highly-functional packaging trend can be induced.

FIGS. 1A to 1E are sectional views sequentially showing a conventional method of manufacturing an electronic component-embedded printed circuit board. Hereinafter, conventional problems will be described with reference to FIGS. 1A to 1E.

First, as shown in FIG. 1A, a substrate 10 including an insulator 3 having a cavity 2 in which an electronic component 1 can be disposed and a tape 4 adhered to one side of the insulator 3 are provided.

Subsequently, as shown in FIG. 1B, the electronic component 1 is disposed in the cavity 2 of the insulator 3. In this case, the electronic component 1 is installed in the cavity 2 using a vacuum adsorption header (not shown), and is supported by the tape 4.

Subsequently, as shown in FIG. 1C, an insulation layer 5 is formed on the substrate including the cavity 2. The insulation layer 5 is formed in the cavity 2 provided therein with the electronic component 1, and thus the electronic component 1 is buried in the insulation layer 5.

Subsequently, as shown in FIG. 1D, the tape 4 is removed from the substrate 10. Since the tape 4 serves to support the electronic component 1 before the electronic component is fixed in the substrate 10 by the insulation layer 5, it is removed after the insulation layer 5 is formed.

Subsequently, as shown in FIG. 1E, an insulation layer 5 is formed even on the one side of the insulator 3 from which the tape 4 was removed, so that the electronic component 1 can be embedded in the substrate 10, and then a circuit layer including vias 6 and a circuit pattern 7 is formed. Here, the vias 6 are electrically connected with the connecting terminals 9 of the electronic component 1.

According to the above-mentioned conventional technology, a process of forming a cavity 2 for disposing an electronic component 1 in a substrate is required, thus causing the problems of it taking much time and expense to perform this process and of it being difficult to precisely dispose the electronic component 1 in the cavity 2. Further, there is a problem in that, after the electronic component 1 is disposed in the cavity 2, a remaining part of the cavity 2 is not completely charged with an insulation layer 5, thus generating a void.

Further, the conventional technology is problematic in that, since connecting terminals 9 of the electronic component 1 cannot be distinguished from the outside of the substrate 10 when the insulation layer 5 is formed on the substrate 10, it is difficult to align the position of via holes for exposing the connecting terminals 9 when forming the via holes in the insulation layer 5. Further, the conventional technology is problematic in that the electronic component 1 is perforated by a laser drill at the time of forming the via holes. Further, the conventional technology is problematic in that the number of I/O pads and pitch of electronic components 1 which can be embedded in the substrate 10 are limited because the connecting terminals 9 of the electronic component 1 are connected with a circuit of the substrate 10 through the via holes formed using a laser drill.

Furthermore, the conventional technology is problematic in that, since a rewiring process is required in order to connect the connecting terminals 9 of the electronic component 1 with the circuit of the substrate 10, design flexibility is decreased, and production costs are increased.

### SUMMARY OF THE INVENTION

Accordingly, the present invention has been made to solve the above-mentioned problems, and the present invention provides an electronic component-embedded printed circuit board which does not need rewiring and can simplify the manufacturing process thereof because connecting patterns formed on a flexible film are directly connected to the connecting terminals of an electronic component using connecting members.

An aspect of the present invention provides an electronic component-embedded printed circuit board, including: a flexible film; an insulation layer formed on one side of the flexible film; an electronic component mounted on the one side of the flexible film in a face-down manner such that the electronic component is buried in the insulation layer; and a circuit layer including a connecting pattern which is formed on the one side of the flexible film and is connected with a connecting terminal of the electronic component by a connecting member.

Here, the electronic component-embedded printed circuit board may further include a via which is connected to the circuit layer and penetrates the flexible film and the insulation layer.

Further, the electronic component-embedded printed circuit board may further include a circuit pattern which is formed on the exposed surface of the flexible film or the insulation layer and is connected with the via.

Further, the electronic component-embedded printed circuit board may further include a build-up layer formed on the exposed surface of the flexible film or the insulation layer.

Further, the connecting member may be solder paste.

Further, the flexible film may be made of polyimide.

Another aspect of the present invention provides a method of manufacturing an electronic component-embedded printed circuit board, including: forming a circuit layer including a connecting pattern on one side of a flexible film; mounting an electronic component on the one side of the flexible film in a face down manner such that a connecting terminal of the electronic component is connected to the connecting pattern by a connecting member; and applying an insulation layer onto one side of the flexible film to allow the electronic component to be buried in the insulation layer.

Here, the method of manufacturing an electronic component-embedded printed circuit board may further include, after the applying of the insulation layer, forming a via which penetrates the flexible film and the insulation layer to make a connection with the circuit layer.

Further, the method of manufacturing an electronic component-embedded printed circuit board may further include: forming a circuit pattern connected with the via on the exposed surface of the flexible film or the insulation layer.

Further, the method of manufacturing an electronic component-embedded printed circuit board may further include, after the applying of the insulation layer, forming a build-up layer on the exposed surface of the flexible film or the insulation layer.

Further, in the mounting of the electronic component, the connecting member may be solder paste.

Further, in the forming of the circuit layer, the flexible film may be made of polyimide.

Various objects, advantages and features of the invention will become apparent from the following description of embodiments with reference to the accompanying drawings.

The terms and words used in the present specification and claims should not be interpreted as being limited to typical meanings or dictionary definitions, but should be interpreted as having meanings and concepts relevant to the technical scope of the present to invention based on the rule according to which an inventor can appropriately define the concept of the term to describe the best method he or she knows for carrying out the invention.

### BRIEF DESCRIPTION OF THE DRAWINGS

The above and other objects, features and advantages of the present invention will be more clearly understood from the following detailed description taken in conjunction with the accompanying drawings, in which:

FIGS. 1A to 1E are sectional views sequentially showing a conventional method of manufacturing an electronic component-embedded printed circuit board;

FIGS. 2 and 3 are sectional views showing electronic component-embedded printed circuit boards according to an embodiment of the present invention; and

FIGS. 4 to 9 are sectional views sequentially showing a method of manufacturing an electronic component-embedded printed circuit board according to an embodiment of the present invention.

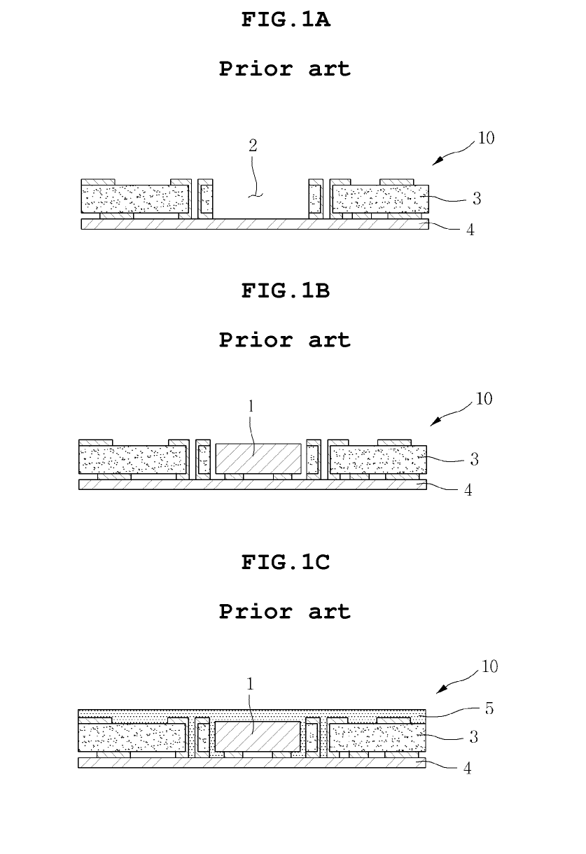

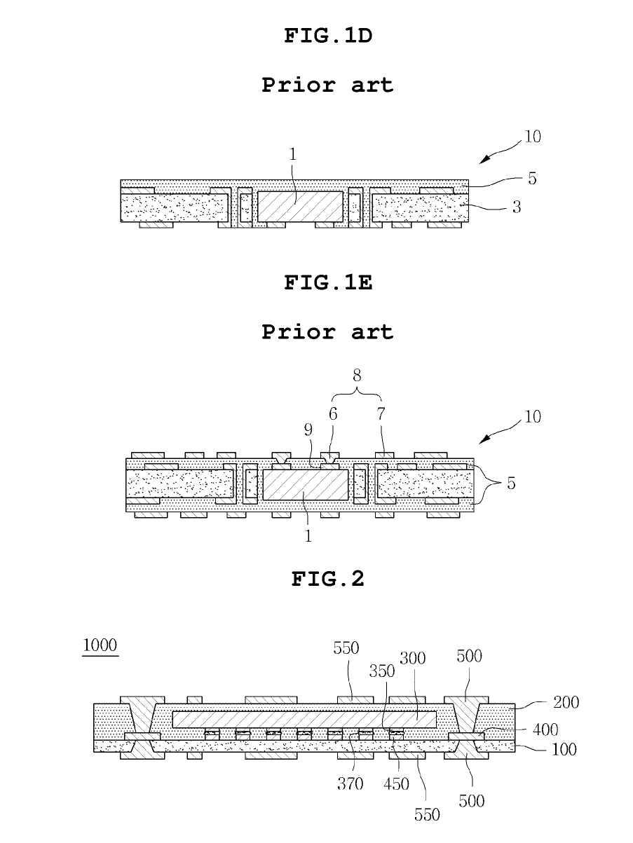

### DESCRIPTION OF THE PREFERRED EMBODIMENTS

The objects, features and advantages of the present invention will be more clearly understood from the following detailed description and preferred embodiments taken in conjunction with the accompanying drawings. Throughout the accompanying drawings, the same reference numerals are used to designate the same or similar components, and redundant descriptions thereof are omitted. In the following description, the terms “one side”, “upper”, “lower” and the like are used to differentiate a certain component from other components, but the configuration of such components should not be construed to be to limited by the terms. Further, in the description of the present invention, when it is determined that the detailed description of the related art would obscure the gist of the present invention, the description thereof will be omitted.

Hereinafter, preferred embodiments of the present invention will be described in detail with reference to the attached drawings.

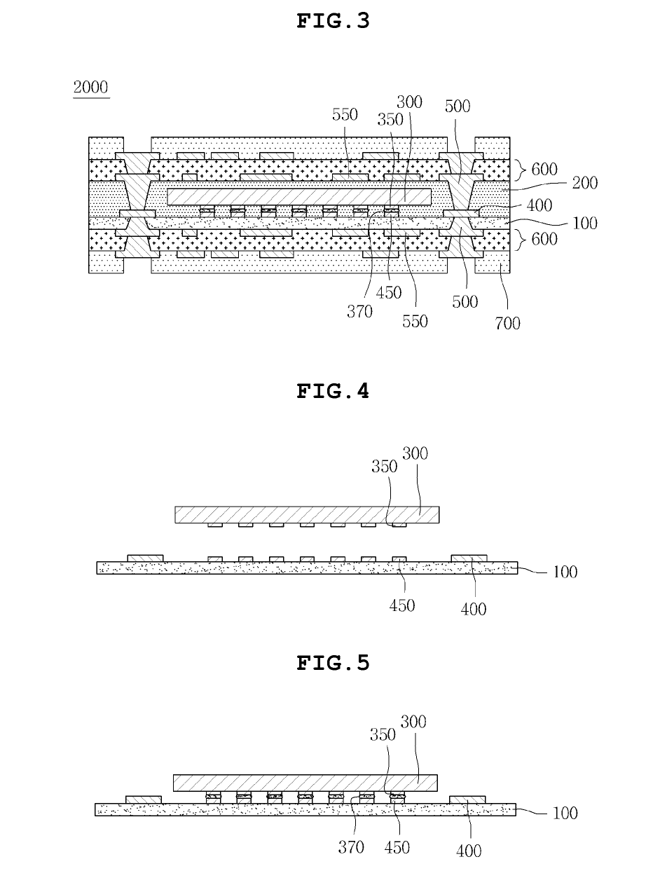

FIGS. 2 and 3 are sectional view showing electronic component-embedded printed circuit boards according to an embodiment of the present invention.

As shown in FIGS. 2 and 3, an electronic component-embedded printed circuit board 1000 according to an embodiment of the present invention includes a flexible film 100, an insulation layer 200 formed on one side of the flexible film 100, an electronic component 300 mounted on the one side of the flexible film 100 in a face-down manner such that the electronic component 300 is buried in the insulation layer 200, a circuit layer 400 including connecting patterns 450 formed on one side of the flexible film 100 and connected with connecting terminals 350 of the electronic component 300 by connecting members 370, and vias 500 which are connected to the circuit layer 400 and penetrate the flexible film 100 and the insulation layer 200 (refer to FIG. 2). Meanwhile, an electronic component-embedded printed circuit board 2000 according to an embodiment of the present invention may further include a build-up layer 600 formed on the exposed surface of the flexible film 100 or the insulation layer 200 (refer to FIG. 3).

The flexible film 100 is a means of mounting the electronic component 300, and is provided on one side thereof with the circuit layer 400 including the connecting patterns 450 which are connected with the connecting terminals 350 of the electronic component 300 by the connecting members 370. Here, the circuit layer 400 including the connecting patterns 450 may be formed through an image forming process, such as exposure or development, and a selective etching process. In this case, the connecting patterns 450 are formed such that they correspond to the connecting terminals 350 of the electronic component 300. Further, the circuit layer 400 can be connected to another circuit layer 550 through the via 500.

Meanwhile, the flexible film 100 may be made of a polymer, such as polyimide (PI), polyester, a liquid crystal polymer or the like. In particular, when the flexible film is made of polyimide having excellent heat resistance, the flexible film does not deform even when heat is applied to the flexible film during a procedure of forming the insulation layer 200 on the flexible film 100.

The electronic component 300 is mounted on one side of the flexible film 100 in a face down manner, and is covered with the insulation layer 200, thus embedding the electronic component 300 in a printed circuit board. Here, the electronic component 300 is a part which is electrically connected to the printed circuit board to conduct a specific function, for example, a capacitor or a semiconductor. Meanwhile, as described above, the connecting terminals 350 of the electronic component 300 are connected to the connecting patterns 450 formed on the flexible film 100 by the connecting members 370. Therefore, the electronic component-embedded printed circuit of the present invention is advantageous in that the production cost thereof can be reduced because additional rewiring is not required, and in that the connections are more reliable because the connecting patterns 450 formed on the flexible film 100 are directly connected to the connecting terminals 350 of the electronic component 300 without forming vias. Here, solder paste is employed as the connecting member 370, and the connecting patterns 450 are connected with the connecting terminals 350 through soldering.

The insulation layer 200 is formed on the flexible film 100 to allow the electronic component 300 to be buried therein, and may be made of any epoxy resin which is generally used in a packaging process. In this case, although the insulation layer 200 can be formed by applying a semi-cured insulating material on the flexible film 100, it may be formed by liquid coating in order to prevent the electronic component 300 from being damaged. Differently from conventional technologies, a cavity is not required to be formed in the insulation layer 200, so that the manufacturing process thereof can be simplified and the production cost thereof can be reduced.

Meanwhile, vias 500, each of which penetrates the insulation layer 200 and the flexible film 100 and is connected to the circuit layer 400 formed on the flexible film 100, may be formed. Here, since the via 500 is formed in both the insulation layer 200 and the flexible film 100, signals and power are transferred from both the insulation layer 200 and the flexible film 100, thus stably driving the electronic component 1. Further, circuit patterns 550 connected with the via 500 may be formed on the exposed surface of the flexible film 100 or the insulation layer 200. The circuit patterns 550 may be selectively formed on only one exposed surface of the flexible film 100 and the insulation layer 200, not both exposed surfaces thereof.

Further, a build-up layer 600 may be formed on the exposed surface of the flexible film 100 or the insulation layer 200 (refer to FIG. 3). The build-up layer 600 can be formed by applying an insulating material onto the exposed surface of the flexible film 100 or the insulation layer 200, forming via holes using a YAG laser drill or a CO₂ laser drill and then performing a semi-additive process. Further, the build-up layer 600 may be selectively formed on only one exposed surface of the flexible film 100 and the insulation layer 200, not both exposed surfaces thereof. Therefore, the electronic component-embedded printed circuit of the present invention is advantageous in that it can be used to manufacture products having a lot of I/O pads because the build-up layer 600 is additionally formed.

Meanwhile, a solder resist layer 700 may be formed on the build-up layer 600 in order to protect an outermost circuit layer. Further, openings may be formed in the solder resist layer 700 in order to electrically connect the printed circuit board to external devices.

FIGS. 4 to 9 are sectional views sequentially showing a method of manufacturing to an electronic component-embedded printed circuit board according to an embodiment of the present invention.

First, as shown in FIG. 4, a circuit layer 400 including connecting patterns 450 is formed on one side of a flexible film 100, and an electronic component 300 is provided. Here, the flexible film 100 may be made of polyimide having excellent heat resistance. Further, the circuit layer 400 including the connecting patterns 450 may be formed through an image forming process, such as exposure or development, and a selective etching process. In this case, since the connecting patterns 450 are connected with connecting terminals 350 of the provided electronic component 300, they are formed such that they correspond to the connecting terminals 350.

Subsequently, as shown in FIG. 5, the electronic component 300 is mounted on one side of the flexible film 100 in a face down manner such that the connecting terminals 350 of the electronic component 300 are connected to the connecting patterns 450 by connecting members 370. Here, solder paste may be used as the connecting member 370, and the connecting patterns 450 may be connected with the connecting terminals 350 through soldering. In this step, since the connecting terminals 350 are directly connected with the connecting patterns 450, additional rewiring is not required, and the reliability of connection is increased.

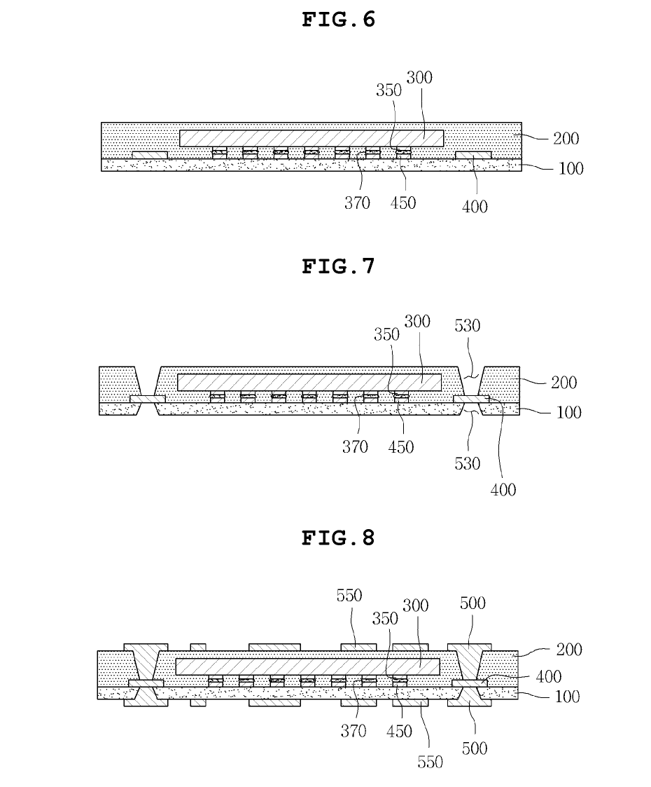

Subsequently, as shown in FIG. 6, an insulation layer 200 is applied onto one side of the flexible film 100 to allow the electronic component 300 to be buried therein. In this case, the insulation layer 200 may be made of a commonly-used epoxy resin. Further, although the insulation layer 200 can be formed by applying a semi-cured insulating material on the flexible film 100, it may be formed by liquid coating in order to protect the electronic component 300. Differently from conventional technologies, in this step, a cavity for accommodating the electronic component 300 is not required to be formed in the insulation layer 200, so that the manufacturing process thereof can be simplified and the production cost thereof can be reduced.

Subsequently, as shown in FIGS. 7 and 8, a via 500 penetrating the flexible film 100 and the insulation layer 200 is connected to the circuit layer 400, and circuit patterns 500 connected with the via 500 are formed on the exposed surface of the flexible film 100 or the insulation layer 200. In this step, first, a via hole 530 penetrating the flexible film 100 and the insulation layer 200 is formed using a YAG or CO₂ laser (refer to FIG. 7). Thereafter, the via 500 can be formed by copper-plating the via hole 530. In this case, since the via 500 is formed upward and downward based on the circuit layer 400, signals and power can be transferred from both the insulation layer 200 and the flexible film 100. In addition, the circuit patterns 500 connected with the via 500 may be formed on the exposed surface of the flexible film 100 or the insulation layer 200 using a subtractive process, a full additive process or a semi-additive process (refer to FIG. 8). In FIG. 8, the circuit patterns are formed on both the exposed surface of the flexible film 100 and the exposed surface of the insulation layer 200, but the circuit patterns 550 may be selectively formed on only one exposed surface of the flexible film 100 and the insulation layer 200.

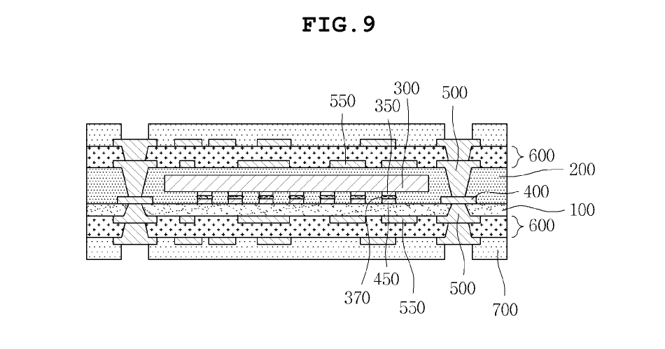

Subsequently, as shown in FIG. 9, a build-up layer 600 is formed on the exposed surface of the flexible film 100 or the insulation layer 200. The build-up layer 600 may be formed by applying an insulating material onto the exposed surface of the flexible film 100 or the insulation layer 200, forming via holes using a YAG laser drill or a CO₂ laser drill and then performing a semi-additive process. In this step, since the build-up layer 600 is additionally formed, the electronic component-embedded printed circuit of the present invention is advantageous in that it can be used to manufacture products having a lot of I/O pads. In FIG. 9, although the build-up layers 600 are formed on both the exposed surface of the flexible film 100 and the exposed surface of the insulation layer 200, the build-up layer 600 may be selectively formed on only one exposed surface of the flexible film 100 and the insulation layer 200, and a two or more layered build up layer may be formed on each of the exposed surfaces thereof. Meanwhile, a solder resist layer 700 may be formed on the build-up layer 600 in order to protect an outermost circuit layer. Further, openings may be formed in the solder resist layer 700 in order to electrically connect the printed circuit board to external devices.

As described above, according to the present invention, since the connecting patterns formed on a flexible film are directly connected to the connecting terminals of an electronic component using connecting members, the position alignment between the connecting patterns and the connecting terminals is easy and the connection therebetween is very reliable. Further, since additional rewiring is not required, the production cost thereof can be reduced.

Further, according to the present invention, since a cavity for mounting the electronic component is not required to be formed in the insulation layer 200, a void is not generated, the manufacturing process thereof can be simplified, and the production cost thereof can be reduced.

Furthermore, according to the present invention, the connecting patterns can be precisely formed such that they correspond to the connecting terminals of the electronic component, and the build-up layer can be additionally formed, so that the electronic component-embedded printed circuit of the present invention can be used to manufacture products having a lot of I/O pads.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

Simple modifications, additions and substitutions of the present invention belong to the scope of the present invention, and the specific scope of the present invention will be clearly defined by the appended claims.

What is claimed is:

1. An electronic component-embedded printed circuit board, comprising:
a flexible film;
an insulation layer formed on one side of the flexible film;
an electronic component mounted on the one side of the flexible film in a face-down manner such that the electronic component is buried in the insulation layer; and
a circuit layer including a connecting pattern which is formed on the one side of the flexible film and is connected with a connecting terminal of the electronic component by a connecting member.

2. The electronic component-embedded printed circuit board according to claim 1, further comprising a via which is connected to the circuit layer and penetrates the flexible film and the insulation layer.

3. The electronic component-embedded printed circuit board according to claim 2, further comprising a circuit pattern which is formed on the exposed surface of the flexible film or the insulation layer and is connected with the via.

4. The electronic component-embedded printed circuit board according to claim 1, further comprising a build-up layer formed on the exposed surface of the flexible film or the insulation layer.

5. The electronic component-embedded printed circuit board according to claim 1, wherein the connecting member is solder paste.

6. The electronic component-embedded printed circuit board according to claim 1, wherein the flexible film is made of polyimide.

7. A method of manufacturing an electronic component-embedded printed circuit board, comprising:
forming a circuit layer including a connecting pattern on one side of a flexible film;
mounting an electronic component on the one side of the flexible film in a face down manner such that a connecting terminal of the electronic component is connected to the connecting pattern by a connecting member; and
applying an insulation layer onto the one side of the flexible film to allow the electronic component to be buried in the insulation layer.

8. The method of manufacturing an electronic component-embedded printed circuit board according to claim 7, further comprising, after the applying of the insulation layer, forming a via which penetrates the flexible film and the insulation layer to make a connection with the circuit layer.

9. The method of manufacturing an electronic component-embedded printed circuit board according to claim 8, further comprising: forming a circuit pattern connected with the via on the exposed surface of the flexible film or the insulation layer.

10. The method of manufacturing an electronic component-embedded printed circuit board according to claim 7, further comprising, after the applying of the insulation layer, forming a build-up layer on the exposed surface of the flexible film or the insulation layer.

11. The method of manufacturing an electronic component-embedded printed circuit board according to claim 7, wherein, in the mounting of the electronic component, the connecting member is solder paste.

12. The method of manufacturing an electronic component-embedded printed circuit board according to claim 7, wherein, in the forming of the circuit layer, the flexible film is made of polyimide.
